(19) United States
(12) Patent Application Publication
(10) Pub. No.: US 2024/0324094 A1
(43) Pub. Date: Sep. 26, 2024

(54) PRINTED CIRCUIT BOARDS AND SEMICONDUCTOR PACKAGES HAVING THE SAME

(71) Applicant: SAMSUNG ELECTRONICS CO., LTD., SUWON-SI (KR)

(72) Inventor: OKGYEONG PARK, SUWON-SI (KR)

(21) Appl. No.: 18/612,282

(22) Filed: Mar. 21, 2024

(30) Foreign Application Priority Data
Mar. 24, 2023 (KR) 10-2023-0039153
Jun. 1, 2023 (KR) 10-2023-0071008

(51) Int. Cl. H05K 1/02; H01L 23/00; H01L 23/498; H01L 25/18; H05K 1/11

(52) U.S. Cl. CPC H05K 1/0225; H01L 23/49833; H01L 23/49838; H05K 1/0245; H05K 1/0271; H05K 1/113; H01L 24/05; H01L 24/06; H01L 24/16; H01L 24/17; H01L 24/32; H01L 24/33; H01L 24/73; H01L 25/18; H01L 2224/0557; H01L 2224/06181; H01L 2224/16145; H01L 2224/16227; H01L 2224/17181; H01L 2224/32145; H01L 2224/32225; H01L 2224/33181; H01L 2224/73204; H05K 2201/096

(57) ABSTRACT

A printed circuit board includes a base board layer including a plurality of board layers which are stacked, the plurality of board layers including a core board layer, a plurality of sub-board layers stacked on each of upper and lower surfaces of the core board layer, and a reinforcing board layer stacked on at least one of the plurality of sub-board layers, a plurality of equipotential plates disposed on a plurality of interconnection layers located on upper and lower surfaces of the plurality of board layers and having differential signal openings and single signal openings, and a substrate interconnection structure including a plurality of board top pads, a plurality of board bottom pads, and a plurality of board interconnection paths connecting the plurality of board top pads to the plurality of board bottom pads through the base board layer.

### CROSS-REFERENCE TO RELATED APPLICATION

This U.S. patent application claims priority under 35 USC § 119 to Korean Patent Application Nos. 10-2023-0039153, filed on Mar. 24, 2023 and 10-2023-0071008, filed on Jun. 1, 2023, in the Korean Intellectual Property Office, the disclosures of which are incorporated by reference in their entireties herein.

### 1. TECHNICAL FIELD

Embodiments of the inventive concept are generally directed to a printed circuit board (PCB) and a semiconductor package having the PCB, and more particularly, to a PCB capable of transmitting a high-speed signal and a semiconductor package having the PCB.

### 2. DISCUSSION OF RELATED ART

As electronic products have been required to be miniaturized and multifunctional and have high-performance, semiconductor chips have been developed that are highly integrated and operate at a high speed. Accordingly, PCBs of semiconductor packages have also been developed to transmit a high-speed signal for semiconductor packages including a semiconductor chip to support high integration and operations performed at high speed.

A PCB may include one or more stacked insulating layers. However, stress may be concentrated to cause cracks to develop along the stacked insulating layers. Thus, there is a need for a PCB capable of transmitting high-speed signals that is more resistant to cracking.

### SUMMARY

At least one embodiment of the inventive concept provides a printed circuit board (PCB) capable of transmitting high-speed signals and a semiconductor package having the PCB.

According to an aspect of the inventive concept, there is provided a printed circuit board including a base board layer including a plurality of board layers which are stacked, the plurality of board layers including a core board layer, a plurality of sub-board layers stacked on each of upper and lower surfaces of the core board layer, and at least one reinforcing board layer, a plurality of equipotential plates disposed on a plurality of interconnection layers located on upper and lower surfaces of the plurality of board layers and having differential signal openings and single signal openings, and a substrate interconnection structure including a plurality of board top pads disposed on the upper surface of the base board layer, a plurality of board bottom pads disposed on the lower surface of the base board layer, and a plurality of board interconnection paths connecting the plurality of board top pads to the plurality of board bottom pads through the base board layer, wherein the plurality of board top pads, the plurality of board bottom pads, and the plurality of board interconnection paths included in the substrate interconnection structure configure a pair of differential signal interconnection structures extending inside the differential signal openings of the plurality of equipotential plates and a single signal interconnection structure extending inside the single signal openings of the plurality of equipotential plates, lower differential signal openings, which are the differential signal openings of the equipotential plates located below the core board layer, among the plurality of equipotential plates, have a same horizontal width and are aligned with each other in a vertical direction, and the at least one reinforcing board layer comprises a first reinforcing board layer stacked on a lower surface of a lowermost sub-board layer among the plurality of sub-board layers.

According to another aspect of the inventive concept, there is provided a printed circuit board including a base board layer including a plurality of board layers which are stacked, the plurality of board layers including a core board layer having a first thickness, a plurality of sub-board layers stacked on each of upper and lower surfaces of the core board layer and having a second thickness that is less than the first thickness, and at least one reinforcing board layer having a third thickness that is less than the first thickness, a plurality of equipotential plates disposed on a plurality of interconnection layers located on upper and lower surfaces of the plurality of board layers and having differential signal openings and single signal openings, a substrate interconnection structure including a plurality of board top pads disposed on the upper surface of the base board layer, a plurality of board bottom pads disposed on the lower surface of the base board layer, and a plurality of board interconnection paths connecting the plurality of board top pads to the plurality of board bottom pads through the base board layer and including a plurality of conductive vias passing through a plurality of conductive patterns disposed on the plurality of interconnection layers and the plurality of board layers, and a solder resist layer covering the upper and lower surfaces of the base board layer and exposing the plurality of board top pads and the plurality of board bottom pads, wherein the plurality of board top pads, the plurality of board bottom pads, and the plurality of board interconnection paths included in the substrate interconnection structure configure a pair of differential signal interconnection structures apart from the plurality of equipotential plates and extending inside the differential signal openings of the plurality of equipotential plates and a single signal interconnection structure spaced apart from the plurality of equipotential plates and extending inside the single signal openings of the plurality of equipotential plates. Lower differential signal openings, which are the differential signal openings of the equipotential plates located below the core board layer, among the plurality of equipotential plates, have a same horizontal width and are aligned with each other in a vertical direction. A horizontal width of a first one of the single signal openings disposed in at least one interconnection layer, among the single signal openings, is different from a horizontal width of a second other one of the single signal openings disposed in the at least one interconnection layer. The at least one reinforcing board layer includes a first reinforcing board layer stacked on a lower surface of a lowermost sub-board layer among the plurality of sub-board layers.

According to another aspect of the inventive concept, there is provided a semiconductor package including a printed circuit board, a plurality of package connection terminals, an interposer, at least one stack structure attached to the interposer and including a first semiconductor chip and a plurality of second semiconductor chips sequentially stacked on the first semiconductor chip in a vertical direction, and at least one third semiconductor chip. The printed circuit board includes a substrate interconnection structure including a base board layer having a plurality of board layers which are stacked; a plurality of equipotential plates disposed on a plurality of interconnection layers located on upper and lower surfaces of the plurality of board layers and having differential signal openings and single signal openings; and a plurality of board top pads disposed on the upper surface of the base board layer, a plurality of board bottom pads disposed on a lower surface of the base board layer, and a plurality of board interconnection paths connecting the plurality of board top pads to the plurality of board bottom pads, and configuring a pair of differential signal interconnection structures extending inside the differential signal openings of the plurality of equipotential plates and a single signal interconnection structure extending inside the single signal openings of the plurality of equipotential plates. The plurality of package connection terminals are attached to the plurality of board top pads. The interposer is electrically connected to the printed circuit board by the plurality of package connection terminals. The at least one third semiconductor chip is attached to the interposer and spaced apart from the at least one stack structure in a horizontal direction. The plurality of external connection terminals are attached to the plurality of board bottom pads. The differential signal openings of at least some of the plurality of equipotential plates have the same horizontal width and are aligned with each other in the vertical direction. The plurality of board layers include a core board layer, a plurality of sub-board layers stacked on each of upper and lower surfaces of the core board layer, and a lower reinforcing board layer stacked on a lower surface of a lowermost sub-board layer, among the plurality of sub-board layers, and including glass cloth.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view of a semiconductor package having a printed circuit board (PCB) according to an embodiment;

FIG. 2 is a partial cross-sectional view of a PCB according to an embodiment;

FIGS. 3A to 3D are planar layouts illustrating a portion of a PCB according to embodiments;

FIGS. 4A and 4B are planar layouts illustrating a portion of a PCB according to embodiment;

FIG. 5 is a partial cross-sectional view of a PCB according to embodiments;

FIGS. 6A to 6D are planar layouts illustrating a portion of a PCB according to embodiments;

FIG. 7 is a planar layout illustrating a portion of a PCB according to an embodiment;

FIGS. 8 to 11 are partial cross-sectional views of PCBs according to embodiments; and

FIGS. 12A to 12C are planar layouts illustrating a portion of the PCB according to an embodiment.

### DETAILED DESCRIPTION

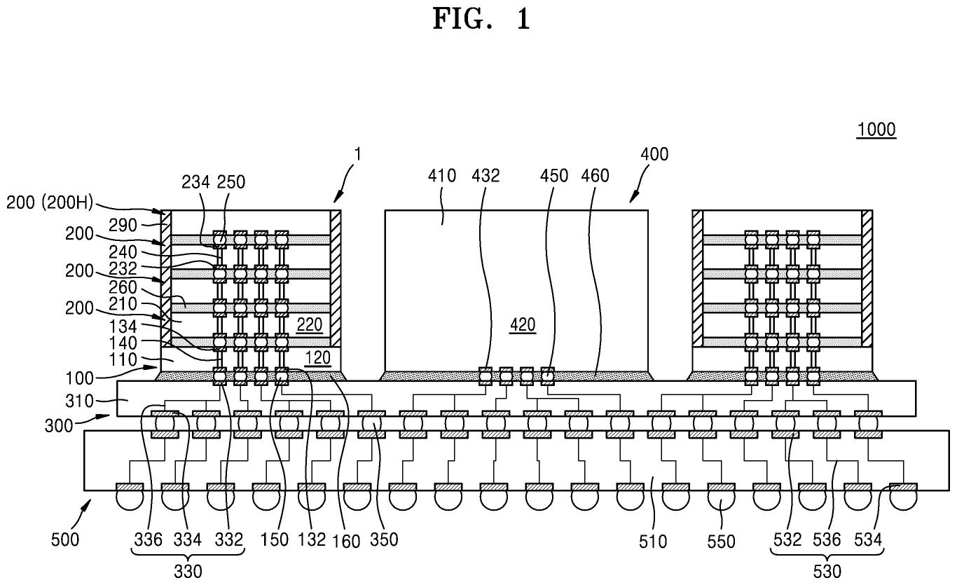

FIG. 1 is a cross-sectional view of a semiconductor package 1000 having a printed circuit board (PCB) 500 according to an embodiment.

Referring to FIG. 1, the semiconductor package 1000 includes at least one stack structure 1 including the PCB 500, an interposer 300 attached to the PCB 500, a first semiconductor chip 100 attached to the interposer 300, and a plurality of second semiconductor chips 200 stacked on the first semiconductor chip 100 and at least one third semiconductor chip 400 attached to the interposer 300. The at least one stack structure 1 and the at least one third semiconductor chip 400 may be spaced apart from each other in a horizontal direction and attached to the interposer 300. The stack structure 1 may be referred to as a memory stack. The at least one third semiconductor chip 400 may be a logic semiconductor chip including a semiconductor device, such as a logic device.

In FIG. 1, the semiconductor package 1000 is illustrated as including two stack structures 1 and one third semiconductor chip 400 attached to the interposer 300 but is not limited thereto. For example, the semiconductor package 1000 may include one, two, four, six, eight, or more stack structures 1. For example, the semiconductor package 1000 may include one, two, four, six, eight, or more third semiconductor chips 400.

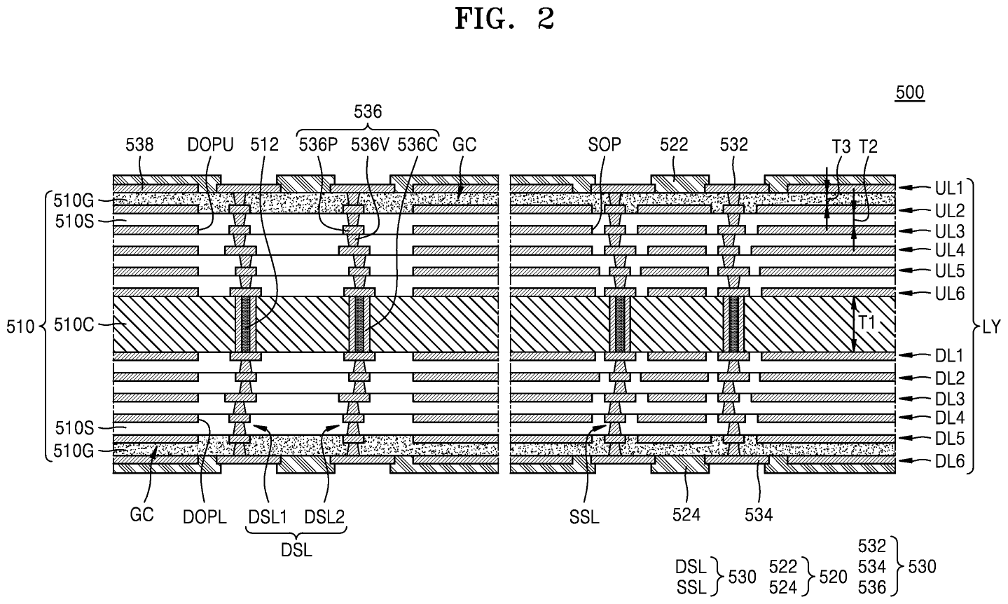

The PCB 500 may include a base board layer 510 and a substrate interconnection structure 530 disposed on upper and lower surfaces of the base board layer 510 and inside the base board layer 510. The substrate interconnection structure 530 may include a plurality of board top pads 532, a plurality of board bottom pads 534, and a plurality of board interconnection paths 536. For example, the board interconnection paths 536 may be wires. The board top pads 532, the board bottom pads 534, and the board interconnection paths 536 included in the substrate interconnection structure 530 may configure a pair of differential signal interconnection structures (DSL in FIG. 2) and a single signal interconnection structure (SSL in FIG. 2).

The board top pads 532 may be disposed on the upper surface of the base board layer 510, the board bottom pads 534 may be disposed on the lower surface of the base board layer 510, and the board interconnection path 536 may electrically connect the board top pads 532 to the board bottom pads 534 through the base board layer 510. In some embodiments, the board interconnection paths 536 may be located inside the base board layer 510 but are not limited thereto. For example, some of the board interconnection paths 536 may extend from the board top pads 532 and/or the board bottom pads 534 and be disposed on the upper surface and/or lower surface of the base board layer 510, and the rest of the board interconnection paths 536 may be located inside the base board layer 510. In an embodiment, one or more of the board interconnection paths 536 are entirely enclosed or surrounded by the base board layer 510.

In an embodiment, the PCB 500 is a multi-layer PCB.

The base board layer 510 may include at least one selected from a phenol resin, an epoxy resin, and polyimide. For example, the base board layer 510 may include at least one selected from a frame retardant 4 (FR4), tetrafunctional epoxy, polyphenylene ether, epoxy/polyphenylene oxide, bismaleimide triazine (BT), thermount, cyanate ester, polyimide, and liquid crystal polymer. In some embodiments, the base board layer 510 may include, for example, polyester telephthalate (PET), fluorinated ethylene propylene (FEP), resin coated paper, a liquid polyimide resin, a polyethylene naphthalate (PEN) film, and the like. The base board layer 510 may be formed by stacking a plurality of base layers.

The board top pads 532 and the board bottom pads 534 may include copper, nickel, stainless steel, or beryllium copper. For example, the board top pads 532 and the board bottom pads 534 may include plated copper. In some embodiments, Ni/Au may be included in surfaces of the board top pads 532 and the board bottom pads 534 opposing the base board layer 510. For example, the Ni/Au may be nickel layer covered by a thin layer of gold.

The board interconnection paths 536 may include a plurality of conductive patterns extending in the horizontal direction and a plurality of conductive vias extending in a vertical direction. The conductive vias may connect two of the conductive lines, the board top pads 532, and the board bottom pads 534 located at different vertical levels. The board interconnection paths 536 may include, for example, electrolytically deposited (ED) copper, rolled-annealed (RA) copper foil, stainless steel foil, aluminum foil, ultra-thin copper foil, sputtered copper, copper alloys, nickel, stainless steel, or beryllium copper.

The PCB 500 may further include a solder resist layer (520 in FIG. 2) covering the upper and lower surfaces of the base board layer 510 and exposing the board top pads 532 and the board bottom pads 534. The solder resist layer 520 may include a top solder resist layer (522 in FIG. 2) and a bottom solder resist layer (524 in FIG. 2). In an embodiment, the top solder resist layer 522 covers the lower surface of the base board layer 510 and does not cover but exposes the board top pads 532. In an embodiment, the bottom solder resist layer 524 covers the upper surface of the base board layer 510 and does not cover but exposes the board bottom pads 534.

A plurality of package connection terminals 350 may be connected to the board top pads 532, and a plurality of external connection terminals 550 may be connected to the board bottom pads 534. The package connection terminals 350 may electrically connect the interposer 300 to the PCB 500. The external connection terminals 550 connected to the board bottom pads 534 may connect the semiconductor package 1000 to an external device. In some embodiments, each of the package connection terminals 350 and the external connection terminals 550 may be a bump, a solder ball, or the like.

The interposer 300 may be used to implement, as a fine pitch type, a vertical connection terminal for connecting the at least one stack structure 1 and the at least one third semiconductor chip 400 to the PCB 500. The interposer 300 may include a base layer 310 and an interposer interconnection structure 330 disposed on upper and lower surfaces of the base layer 310 and inside the base layer 310. The interposer interconnection structure 330 may include a plurality of interposer top pads 332, a plurality of interposer bottom pads 334, and a plurality of interposer interconnection paths 336. For example, the interposer interconnection paths 336 may be wires. The interposer top pads 332 may be disposed on the upper surface of the base layer 310, the interposer bottom pads 334 may be disposed on the lower surface of the base layer 310, and the interposer interconnection paths 336 may electrically connect the interposer top pads 332 to the interposer bottom pads 334 through the base layer 310. The interposer connection terminals 350 may be attached to the interposer bottom pads 334. The interposer connection terminals 350 may be located between the board top pads 532 and the interposer bottom pads 334 to electrically connect the interposer 300 to the PCB 500. In an embodiment, one or more of the interposer interconnection paths 336 is entirely enclosed or surrounded by the base layer 310.

The base layer 310 may include a semiconductor material, glass, ceramic, or plastic. For example, the base layer 310 may include silicon. In some embodiments, the interposer 300 may be a silicon interposer in which the base layer 310 is formed from a silicon semiconductor substrate.

In some embodiments, each of the interposer interconnection paths 336 may be through-electrodes passing through the base layer 310. For example, the interposer interconnection paths 336 may pass through the base layer 310 from the upper surface to the lower surface of the base layer 310 to electrically connect the interposer top pads 332 to the interposer bottom pads 334 corresponding to each other. When each of the interposer interconnection paths 336 is a through-electrode, each of the interposer interconnection paths 336 may include a conductive plug passing through the base layer 310 and a conductive barrier film surrounding the conductive plug. The conductive plug may include copper (Cu) or tungsten (W), and the conductive barrier film may include a metal or a conductive metal nitride. The conductive plug may have a cylindrical shape, and the conductive barrier film may have a cylindrical shape surrounding a sidewall of the conductive plug. A plurality of via insulating films may be located between the base layer 310 and each of the interposer interconnection paths 336 to surround sidewalls of the interposer interconnection paths 336. The via insulating films may prevent direct contact between the base layer 310 and the interposer interconnection paths 336. The via insulating film may include an oxide layer, a nitride layer, a carbide layer, a polymer, or combinations thereof.

In an embodiment, the interposer 300 further includes a redistribution structure disposed on the upper surface of the base layer 310 and formed through a redistribution process. The redistribution structure may include a plurality of redistribution interconnection patterns, a plurality of redistribution vias, and a redistribution insulating layer. In some embodiments, the interposer top pads 332 may be part of the redistribution interconnection patterns.

In some other embodiments, the interposer 300 may further include an interconnection structure disposed on the upper surface of the base layer 310 and formed through a semiconductor back end of interconnection (BEOL) process. The interconnection structure may include a plurality of interconnection line patterns, a plurality of interconnection vias, and an interconnection insulating layer. In some embodiments, the interposer top pads 332 may be part of the interconnection line patterns.

A plurality of first chip connection terminals 150 and a plurality of third chip connection terminals 450 may be attached to the interposer top pads 332. In some embodiments, each of the first chip connection terminals 150 and the third chip connection terminals 450 may be a bump, a solder ball, or the like. A first underfill layer 160 surrounding the first chip connection terminals 150 may be located between the interposer 300 and the stack structure 1, and a second underfill layer 460 surrounding the third chip connection terminals 450 may be located between the interposer 300 and the third semiconductor chip 400. The first underfill layer 160 and the second underfill layer 460 may include, for example, an epoxy resin formed by a capillary underfill method. In an embodiment, the first underfill layer 160 and the second underfill layer 460 are non-conductive films (NCF).

The stack structure 1 may include the first semiconductor chip 100 and the second semiconductor chips 200. In FIG. 1, the at least one stack structure 1 is illustrated as including one first semiconductor chip 100 and four second semiconductor chips 200 but is not limited thereto. For example, the stack structure 1 may include two or more second semiconductor chips 200. In some embodiments, one stack structure 1 may include a multiple of 4 second semiconductor chips 200. The second semiconductor chips 200 may be sequentially stacked on the first semiconductor chip 100 in the vertical direction. Each of the first semiconductor chip 100 and the second semiconductor chips 200 may be sequentially stacked with active surfaces facing downward, that is, toward the interposer 300.

The first semiconductor chip 100 and the second semiconductor chips 200 may include dynamic random access memory (DRAM), static random access memory (SRAM), flash memory, electrically erasable and programmable read-only memory (EEPROM), phase-change random access memory (PRAM), magnetic random access memory (MRAM), or resistive random access memory (RRAM).

In an embodiment, the first semiconductor chip 100 does not include a memory cell. The first semiconductor chip 100 may include a test logic circuit, such as a serial-parallel conversion circuit, a design for test (DFT), a joint test action group (JTAG), and a memory built-in self-test (MBIST), and a signal interface circuit, such as PHY. The second semiconductor chips 200 may include memory cells. For example, the first semiconductor chip 100 may be a buffer chip for controlling the second semiconductor chips 200.

In some embodiments, the first semiconductor chip 100 may be a buffer chip for controlling a high bandwidth memory (HBM) DRAM, and the second semiconductor chips 200 may be a memory cell chip having a cell of HBM DRAM controlled by the first semiconductor chip 100. The first semiconductor chip 100 may be referred to as a buffer chip or a master chip, and the second semiconductor chip 200 may be referred to as a slave chip or a memory cell chip. The stack structure 1 including the first semiconductor chip 100 and the second semiconductor chips 200 sequentially stacked on the first semiconductor chip 100 may be referred to as an HBM DRAM device.

The first semiconductor chip 100 includes a first substrate 110, a plurality of first front connection pads 132, a plurality of first rear connection pads 134, and a plurality of first through-electrodes 140. The second semiconductor chip 200 includes a second substrate 210, a plurality of second front connection pads 232, a plurality of second rear connection pads 234, and a plurality of second through-electrodes 240.

The first substrate 110 and the second substrate 210 may include silicon (Si). Alternatively, the first substrate 110 and the second substrate 210 may include a semiconductor device, such as germanium (Ge), or a compound semiconductor, such as silicon carbide (SiC), gallium arsenide (GaAs), indium arsenide (InAs), and indium phosphide (InP). The first substrate 110 and the second substrate 210 may include an active surface and an inactive surface opposite to the active surface. The first substrate 110 and the second substrate 210 may include a plurality of individual devices of various types on the active surface. The individual devices may include various microelectronics devices, for example, a metal-oxide-semiconductor field effect transistor (MOSFET), such as a complementary metal-insulator-semiconductor (CMOS) transistor, an active device, a passive device, and the like. The active surface and the inactive surface of the first substrate 110 may be respectively referred to as a first active surface and a first inactive surface, and the active surface and the inactive surface of the second substrate 210 may be respectively referred to as a second active surface and a second inactive surface.

The first semiconductor chip 100 may include a first semiconductor device 120 and the second semiconductor chip 200 may include a second semiconductor device 220 constituted by individual devices. The first semiconductor device 120 may be disposed on the first active surface of the first substrate 110. The first front connection pads 132 and the first rear connection pads 134 may be respectively disposed on the first active surface and the first inactive surface of the first substrate 110, respectively. The first through-electrodes 140 may vertically pass through at least a portion of the first substrate 110 to electrically connect the first front connection pads 132 to the first rear connection pads 134.

The second semiconductor device 220 may be formed on the second active surface of the second substrate 210. The second front connection pads 232 and the second rear connection pads 234 may be respectively disposed on the second active surface and the second inactive surface of the second substrate 210. The second through-electrodes 240 may vertically pass through at least a portion of the second substrate 210 to electrically connect the second front connection pads 232 to the second rear connection pads 234. The second through-electrodes 240 may be electrically connected to the first through-electrodes 140.

The stack structure 1 may be electrically connected to the interposer 300 through the first front connection pads 132. In some embodiments, the first chip connection terminals 150 may be located between the first front connection pads 132 and the interposer top pads 332 to electrically connect the first front connection pads 132 to the interposer top pads 332. A plurality of second chip connection terminals 250 may be respectively attached to the second front connection pads 232 of each of the second semiconductor chips 200. The second chip connection terminals 250 may be located between the first rear connection pads 134 of the first semiconductor chip 100 and the second front connection pads 232 of the lowermost second semiconductor chip 200 among the second semiconductor chips 200 and between the second front connection pads 232 of the rest of the second semiconductor chips 200 among the second semiconductor chips 200 and the second rear connection pads 234 of the other lower second semiconductor chip 200 to electrically connect the first semiconductor chip 100 to the second semiconductor chips 200. Each of the second chip connection terminals 250 may be a bump, a solder ball, or the like.

In an embodiment, among the second semiconductor chips 200, a second semiconductor chip 200H located at the uppermost end farthest from the first semiconductor chip 100 does not include the second rear connection pad 234 and the second through-electrode 240. In an embodiment, among the second semiconductor chips 200, a thickness of the second semiconductor chip 200H located at the uppermost end disposed farthest from the first semiconductor chip 100 has a value greater than those of the other second semiconductor chips 200.

An insulating adhesive layer 260 may be located between the first semiconductor chip 100 and each of the second semiconductor chips 200. The insulating adhesive layer 260 may be attached to the lower surface of each of the second semiconductor chips 200 to attach each of the second semiconductor chips 200 to a lower structure, for example, the first semiconductor chip 100 or another second semiconductor chip 200 located therebelow among the second semiconductor chips 200. The insulating adhesive layer 260 may include a non-conductive film (NCF), a non-conductive paste (NCP), an insulating polymer, or an epoxy resin. The insulating adhesive layer 260 may surround the second chip connection terminals 250 and fill a space between the first semiconductor chip 100 and each of the second semiconductor chips 200.

In an embodiment, a horizontal width and area of the first semiconductor chip 100 has greater values than a horizontal width and area of each of the second semiconductor chips 200. For example, each of the second semiconductor chips 200 may overlap the first semiconductor chip 100 in the vertical direction. In some embodiments, each of the second semiconductor chips 200 overlap each other in the vertical direction. The second semiconductor chips 200 may be aligned with one another in the vertical direction. The first semiconductor chip 100 may extend further than the outer boundaries of the semiconductor chips 200.

The stack structure 1 may further include a chip molding layer 290 surrounding the second semiconductor chips 200 and the insulating adhesive layers 260 on the upper surface of the first semiconductor chip 100, that is, the first inactive surface of the first substrate 110. The chip molding layer 290 may cover the upper surface of the first semiconductor chip 100, that is, the first inactive surface of the first substrate 110, and may cover side surfaces of the second semiconductor chips 200. In an embodiment, a side surface of the first semiconductor chip 100 and a side surface of the chip molding layer 290 corresponding to each other are aligned in a vertical direction (a Z direction) to form the same plane. For example, the first semiconductor chip 100 need not extend beyond an outer boundary of the chip molding layer 290. In some embodiments, the chip molding layer 290 covers the side surfaces of the second semiconductor chips 200 and does not cover but exposes the upper surface of the second semiconductor chip 200H located at the uppermost end. That is, the inactive surface of the second substrate 210 of the second semiconductor chip 200H located at the uppermost end may be exposed. The chip molding layer 290 may include, for example, an epoxy molding compound (EMC).

The third semiconductor chip 400 may include a third substrate 410 and a plurality of third front connection pads 432. The third front connection pads 432 may be disposed on a third active surface of the third substrate 410. Because the third substrate 410 is substantially similar to the first substrate 110 and the second substrate 210, a detailed description thereof is omitted. The third substrate 410 may have an active surface and an inactive surface opposite to the active surface. The active surface and the inactive surface of the third substrate 410 may be respectively referred to as a third active surface and a third inactive surface. The third semiconductor chip 400 may include a third semiconductor device 420. The third semiconductor device 420 may be formed on the third active surface of the third substrate 410.

The third semiconductor chip 400 may be electrically connected to the interposer 300 through the third front connection pads 432. In some embodiments, a plurality of third chip connection terminals 450 are located between the third front connection pads 432 and the interposer top pads 332 to electrically connect the third front connection pads 432 to the interposer top pads 332.

The at least one third semiconductor chip 400 may include one of, for example, a central processing unit (CPU) chip, a graphics processing unit (GPU) chip, an application processor (AP) chip, an application specific integrated circuit (ASIC) chip, or other processing chips.

In some embodiments, the semiconductor package 1000 may further include a package molding layer (not shown) surrounding the at least one stack structure 1 and the at least one third semiconductor chip 400 on the interposer 300. The package molding layer may include, for example, an EMC. In some embodiments, the package molding layer does not cover an upper surface of the second semiconductor chip 200H located at the uppermost end and an upper surface of the at least one third semiconductor chip 400. For example, the package molding layer may cover a side surface of the at least one third semiconductor chip 400. In some embodiments, the package molding layer surrounds a side surface of the chip molding layer 290 surrounding the second semiconductor chips 200 included in the at least one stack structure 1 and a side surface of the first semiconductor chip 100 included in the at least one stack structure 1. For example, the upper surface of the uppermost second semiconductor chip 200H, the upper surface of the at least one third semiconductor chip 400, the chip molding layer 290, and the upper surface of the package molding layer may be coplanar with each other. In some embodiments, the side surface of the interposer 300 and the side surface of the package molding layer corresponding to each other are aligned in the vertical direction to form the same plane.

FIG. 2 is a partial cross-sectional view of the PCB 500 according to an embodiment.

Referring to FIG. 2, the PCB 500 includes the base board layer 510 and the substrate interconnection structure 530 disposed on upper and lower surfaces of the base board layer 510 and inside the base board layer 510. The substrate interconnection structure 530 may include the board top pads 532, the board bottom pads 534, and the board interconnection paths 536. The board top pads 532, the board bottom pads 534, and the board interconnection paths 536 included in the substrate interconnection structure 530 may constitute a pair of differential signal interconnection structures DSLs and a single signal interconnection structure SSL. The pair of differential signal interconnection structures DSLs may be spaced apart from each other in a horizontal direction and may extend in the vertical or horizontal direction.

The PCB 500 may further include the solder resist layer 520 including the top solder resist layer 522 and the bottom solder resist layer 524 respectively covering the upper and lower surfaces of the base board layer 510. In an embodiment, the top solder resist layer 522 covers the upper surface of the base board layer 510 but does not cover and exposes the board top pads 532. An upper surface of the board top pads 532 may be lower than an upper surface of the top solder resist layer 522. In an embodiment, the bottom solder resist layer 524 covers the lower surface of the base board layer 510 but does not cover and exposes the board bottom pads 534. A lower surface of the board bottom pads 534 may be lower than a lower surface of the bottom solder resist layer 524.

Each of the top solder resist layer 522 and the bottom solder resist layer 524 may include a polyimide film, a polyester film, a flexible solder mask, a photo-imageable coverlay (PIC), or a photo-imageable solder resist, and the like. Each of the top solder resist layer 522 and the bottom solder resist layer 524 may be formed by thermally curing thermosetting ink applied by, for example, a silk screen-printing method or an inkjet method. Each of the top solder resist layer 522 and the bottom solder resist layer 524 may be formed by, for example, removing a portion of a photosensitive solder resist applied by a screen method or a spray coating method through exposure and development and then thermally curing a resultant structure. Each of the top solder resist layer 522 and the bottom solder resist layer 524 may be formed by laminating, for example, a polyimide film or a polyester film.

The board top pads 532 may be disposed on the upper surface of the base board layer 510, the board bottom pads 534 may be disposed on the lower surface of the base board layer 510, and the board interconnection paths 536 may electrically connect the board top pads 532 to the board bottom pads 534 through the base board layer 510. In some embodiments, the board interconnection paths 536 may be located inside the base board layer 510 but are not limited thereto. For example, some of the board interconnection paths 536 may extend from the board top pads 532 and/or the board bottom pads 534 and be disposed on the upper and/or lower surface of the base board layer 510, and the rest of the board interconnection paths 536 may be located inside the base board layer 510. Some of the board interconnection paths 536 extending from the board top pads 532 and/or the board bottom pads 534 and disposed on the upper and/or lower surfaces of the base board layer 510 may be covered by the top solder resist layer 522 and/or the bottom solder resist layer 524. For example, a board interconnection path 536 could contact a board top pad 532 and extend through the base board layer 510 without contacting the board bottom pad 534, or vice versa.

The base board layer 510 may be formed by stacking a plurality of board layers. The board layers may include a core board layer 510C, a plurality of sub-board layers 510S, and at least one reinforcing board layer 510G. In some embodiments, the base board layer 510 may include a core board layer 510C, sub-board layers 510S and at least one reinforcing board layer 510G stacked on an upper surface of the core board layer 510C, and sub-board layers 510S and at least one reinforcing board layer 510G stacked on a lower surface of the core board layer 510C. For example, the base board layer 510 may include the core board layer 510C, the sub-board layers 510S and the reinforcing board layer 510G sequentially stacked on the upper surface of the core board layer 510C, and the sub-board layer 510S and the reinforcing board layer 510G sequentially stacked on the lower surface of the core board layer 510C. For example, among the board layers stacked on the upper surface of the core board layer 510C, the uppermost board layer may be the reinforcing board layer 510G and the rest may be sub-board layers 510S, and among the board layers stacked on the lower surface of the core board layer 510C, the lowermost board layer may be the reinforcing board layer 510G, and the rest may be the sub-board layers 510S. That is, the reinforcing board layer 510G may be disposed on each of the uppermost and lowermost ends of the base board layer 510 included in the PCB 500. The core board layer 510C has a first thickness T1, the sub-board layer 510S has a second thickness T2, and the reinforcing board layer 510G has a third thickness T3. In an embodiment, the first thickness T1 has a value greater than that of each of the second thickness T2 and the third thickness T3. In an embodiment, the second thickness T2 has a value equal to or less than that of the third thickness T3. In some embodiments, the second thickness T2 and the third thickness T3 may have the same or substantially the same value.

The board layer, the sub-board layer 510S, and the reinforcing board layer 510G stacked on the upper surface of the core board layer 510C may be referred to as an upper board layer, an upper sub-board layer, and an upper reinforcing board layer, and the board layer, the sub-board layer 510S, and the reinforcing board layer 510G stacked on the lower surface of the core board layer 510C may be referred to as a lower board layer, a lower sub-board layer, and a lower reinforcing board layer. In FIG. 2, it is illustrated that the PCB 500 includes five upper board layers and five lower board layers. The five upper board layers include one upper reinforcing board layer and four upper sub-board layers, and the five lower board layers include one lower reinforcing board layer and four sub-board layers, but the inventive concept is not limited thereto by way of example. For example, the PCB 500 may include two or more upper board layers and two or more lower board layers, and the two or more upper board layers include one upper reinforcing board layer and one or more upper sub-board layers, and the two or more lower board layers may include one lower reinforcing layer and one or more lower sub-board layers.

The base board layer 510 may include the reinforcing board layer 510G, at least one sub-board layer 510S, the core board layer 510C, at least one sub-board layer 510S, and the reinforcing board layer 510G sequentially stacked from bottom to top.

Each of the core board layer 510C, the sub-board layer 510S, and the reinforcing board layer 510G may include at least one material selected from a phenol resin, an epoxy resin, and polyimide. In an embodiment, unlike the core board layer 510C and the sub-board layer 510S, the reinforcing board layer 510G further includes a reinforcing member GC. In an embodiment, the reinforcing member GC is a glass cloth. For example, the sub-board layer 510S may not include glass cloth. In an embodiment, the glass cloth is a fiberglass cloth that is composed of woven glass fibers. In some embodiments, the reinforcing board layer 510G includes the reinforcing member GC including glass cloth bundles or fibers orthogonal to each other to form a matrix pattern. For example, the reinforcing member GC may include glass cloth bundles or fibers having a width of several hundreds μm and formed by binding together glass cloth having a diameter of several μm. In some other embodiments, the reinforcing member GC may include non-woven glass fabric or aramid fiber. The reinforcing member GC may include non-woven fabrics made with carbon fiber, fiberglass, aramid or acro-veil fibers.

The board interconnection paths 536 may include a plurality of conductive patterns 536P extending in the horizontal direction and a plurality of conductive vias 536C and 536V extending in the vertical direction. Each of the conductive patterns 536P may be disposed on upper and lower surfaces of the board layers included in the base board layer 510. The conductive vias 536C and 536V may connect the conductive patterns 536P located on different interconnection layers LY. The conductive vias 536C and 536V may include a core via 536C passing through the core board layer 510C and a sub-via 536V passing through the sub-board layer 510S. The core via 536C may connect the conductive patterns 536P disposed on the upper and lower surfaces of the core board layer 510C, and the sub-via 536V may connect the conductive patterns 536P disposed on the upper and lower surfaces of the sub-board layer 510S. In some embodiments, the core via 536C may has a hollow cylindrical shape. The sub-via 536V may have a solid cylindrical shape but is not limited thereto. In some embodiments, the sub-via 536V has a hollow cylindrical shape. In some embodiments, the inside of the core via 536C and/or the sub-via 536V having a hollow cylindrical shape is filled with a filling insulating layer 512.

The PCB 500 may have a plurality of interconnection layers LY. The interconnection layers LY refer to a place having a circuit interconnection forming an electrical path on the same plane. Each of the interconnection layers LY may be at different vertical levels. Portions of the board interconnection paths 536 extending in the horizontal direction may be disposed in the interconnection layers LY, respectively. The interconnection layers LY may be located on upper and lower surfaces of the board layers included in the base board layer 510. For example, the number of interconnection layers LY may be greater by one than the number of board layers included in the base board layer 510.

For example, the PCB 500 may have a first upper interconnection layer UL1, a second upper interconnection layer UL2, a third upper interconnection layer UL3, a fourth upper interconnection layer UL4, a fifth upper interconnection layer UL5, and a sixth upper interconnection layer UL6 sequentially from the uppermost end of the PCB 500 to the core board layer 510C and may have a first lower interconnection layer DL1, a second lower interconnection layer DL2, a third lower interconnection layer DL3, a fourth lower interconnection layer DL4, a fifth lower interconnection layer DL5, and a sixth lower interconnection layer DL6 sequentially from the core board layer 510C to the lowermost end of the PCB 500.

The PCB 500 may further include a plurality of equipotential plates 538 disposed on at least some of the interconnection layers LY, for example, the first upper interconnection layer UL1, the second upper interconnection layer UL2, the third upper interconnection layer UL3, the fourth upper interconnection layer UL4, the fifth upper interconnection layer UL5, the sixth upper interconnection layer UL6, the first lower interconnection layer DL1, the second lower interconnection layer DL2, the third lower interconnection layer DL3, the fourth lower interconnection layer DL4, the fifth lower interconnection layer DL5, and the sixth lower interconnection layer DL6. In some embodiments, each of the equipotential plates 538 may include a power plate provided with power or a ground plate provided with ground.

The equipotential plate 538 located on each of the first upper interconnection layer UL1, the second upper interconnection layer UL2, the third upper interconnection layer UL3, the fourth upper interconnection layer UL4, the fifth upper interconnection layer UL5, and the sixth upper interconnection layer UL6 may be disposed on the upper surfaces of the board layers located below, for example, the upper surface of the core board layer 510C, the upper surface of the sub-board layer 510S, and the upper surface of the reinforcing board layer 510G but may not be buried inside board layers located above, for example, the core board layer 510C, the sub-board layer 510S, and the reinforcing board layer 510G. The equipotential plate 538 located on each of the first upper interconnection layer UL1, the second upper interconnection layer UL2, the third upper interconnection layer UL3, the fourth upper interconnection layer UL4, the fifth upper interconnection layer UL5, and the sixth upper interconnection layer UL6 may be buried inside the board layer located above, for example, the sub-board layer 510S or the reinforcing board layer 510G or may be buried inside the top solder resist layer 522 located above. For example, an equipotential plate 538 may be covered by a top solder resist layer 522 or a bottom solder resist layer 524.

The equipotential plate 538 located on each of the first lower interconnection layer DL1, the second lower interconnection layer DL2, the third lower interconnection layer DL3, the fourth lower interconnection layer DL4, the fifth lower interconnection layer DL5, and the sixth lower interconnection layer DL6 may be disposed on the lower surface of the board layer located above, for example, the lower surface of the core board layer 510C, the lower surface of the sub-board layer 510S, or the lower surface of the reinforcing board layer 510G, but may not be buried inside the board layer located below, for example, the core board layer 510C, the sub-board layer 510S, or the reinforcing board layer 510G. The equipotential plate 538 located on each of the first lower interconnection layer DL1, the second lower interconnection layer DL2, the third lower interconnection layer DL3, the fourth lower interconnection layer DL4, the fifth lower interconnection layer DL5, and the sixth lower interconnection layer DL6 may be buried inside the board layer located below, for example, inside the sub-board layer 510S or the reinforcing board layer 510G or inside the bottom solder resist layer 524 located below.

The equipotential plates 538 may have a plurality of differential signal openings DOPU and DOPL and a plurality of single signal openings SOP. The differential signal openings DOPU and DOPL may respectively include a plurality of upper differential signal openings DOPU and a plurality of lower differential signal openings DOPL.

The equipotential plates 538 located above the core board layer 510C may have the upper differential signal openings DOPU, and the equipotential plates 538 located below the core board layer 510C may have the lower differential signal openings DOPL. That is, the equipotential plates 538 located on the first upper interconnection layer UL1, the second upper interconnection layer UL2, the third upper interconnection layer UL3, the fourth upper interconnection layer UL4, the fifth upper interconnection layer UL5, and the sixth upper interconnection layer UL6 may have the upper differential signal openings DOPU, and the equipotential plates 538 located on the first lower interconnection layer DL1, the second lower interconnection layer DL2, the third lower interconnection layer DL3, the fourth lower interconnection layer DL4, the fifth lower interconnection layer DL5, and the sixth lower interconnection layer DL6 may have the lower differential signal openings DOPL.

The board top pads 532, the bottom surface pads 534, and the board interconnection paths 536 included in the substrate interconnection structure 530 may configure the pair of differential signal interconnection structure DSL and the single signal interconnection structure SSL. The pair of differential signal interconnection structures DSL may include a first differential signal interconnection structure DSL1 and a second differential signal interconnection structure DSL2 spaced apart from each other and through which signals having opposite phases flow. The pair of differential signal interconnection structures DSL may extend along inside each of the upper differential signal openings DOPU and each of the lower differential signal openings DOPL. The single signal interconnection structure SSL may extend along inside each of the single signal openings SOP. A first stack of equipotential plates 538 may be located to the left of the first differential signal interconnection structure DSL1 and a second stack of the equipotential plates 538 may be located to the right of the second differential signal interconnection structure DSL2. A third stack of equipotential plates 538 may be located to the left of the single signal interconnection structure SSL and a fourth stack of the equipotential plates 538 may be located to the right of the single signal interconnection structure SSL.

In one interconnection layer LY, the conductive pattern 536P, the board top pad 532, or the board bottom pad 534 of the first differential signal interconnection structure DSL1 or the conductive pattern 536P, the board top pad 532, or the board bottom pad 534 of the second differential signal interconnection structure DSL2 included in the pair of differential signal interconnection structures DSL may be located inside one differential signal opening DOPU or DOPL. In one interconnection layer LY, the conductive pattern 536P, the board top pad 532, or the board bottom pad 534 of the single signal interconnection structure SSL may be located inside the single signal opening SOP. That is, in one interconnection layer LY, two conductive patterns 536P, two board top pads 532, or two board bottom pads 534, that is, the conductive pattern 536P, the board top pad 532, or the board bottom pad 534 of the first differential signal interconnection structure DSL1 and the conductive pattern 536P, the board top pad 532, or the board bottom pad 534 of the second differential signal interconnection structure DSL2, may be located inside the one differential signal opening DOPU or DOPL, and one conductive pattern 536P, one board top pad 532, or one board bottom pad 534 of one single signal interconnection structure SSL may be located inside one single signal opening SOP.

In an embodiment, each of the upper differential signal openings DOPU and the lower differential signal openings DOPL have the same or substantially the same horizontal width. Each of the upper differential signal openings DOPU and the lower differential signal openings DOPL may be vertically aligned and overlap each other.

The single signal opening SOP disposed on at least one interconnection layer LY among the single signal openings SOP may have a horizontal width that is different from that of the single signal opening SOP disposed on at least one other interconnection layer LY. For example, the edge of the conductive pattern 536P, the board top pad 532, or the board bottom pad 534 of the single signal interconnection structure SSL disposed in each of the single signal openings SOP may be spaced apart from the edge of the equipotential plate 538 defining each of the single signal openings SOP with substantially equal spacing. In some embodiments, a horizontal width of each of the single signal openings SOP may be proportional to a horizontal width of the conductive pattern 536P, the board top pad 532, or the board bottom pad 534 located inside each of the single signal openings SOP.

The PCB 500 according to an embodiment of the inventive concept includes the differential signal openings DOPU and DOPL for preventing noise from occurring in the pair of differential signal interconnection structures DSL and the reinforcing board layer 510G including the reinforcing member GC is disposed at the uppermost and lowermost ends of the base board layer 510, so that the base board layer 510 may be prevented from being cracked due to stress caused by the external connection terminals (550 in FIG. 1) attached to the board bottom pads 534 and/or the package connection terminals (350 in FIG. 1) attached to the board top pads 532 or propagation of cracking that occurs into the base board layer 510 may be prevented.

Therefore, the PCB 500 according to the inventive concept may prevent defects due to cracks, while transmitting high-speed signals without noise.

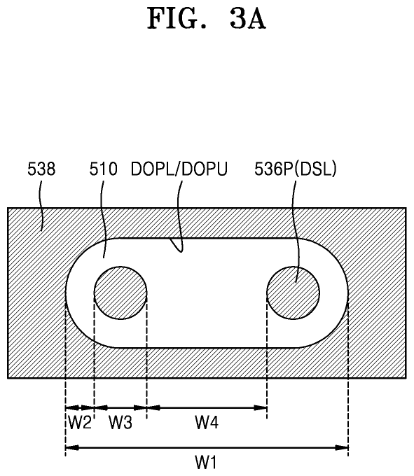

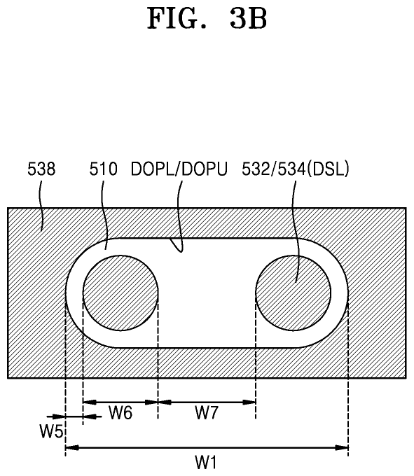

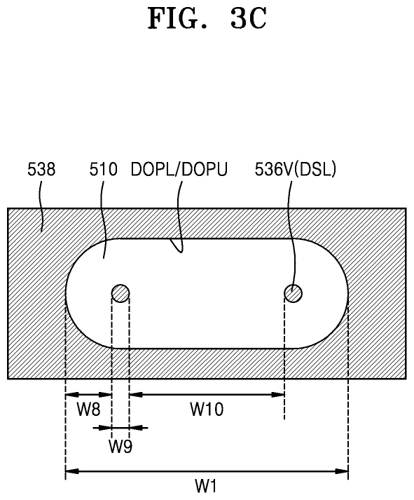

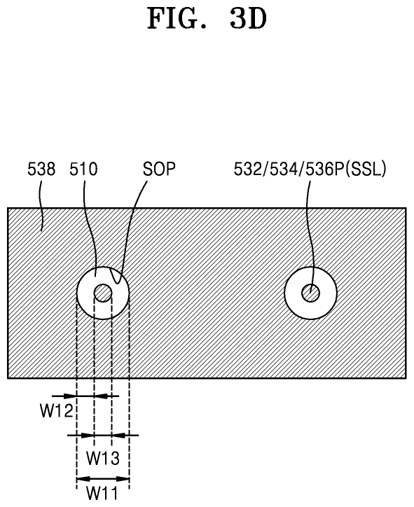

FIGS. 3A to 3D are planar layouts illustrating a portion of the PCB according to embodiments.

Referring to FIGS. 2 and 3A together, the equipotential plate 538 may have the differential signal opening DOPU/DOPL. A pair of differential signal interconnection structures DSL may be located inside the differential signal opening DOPU/DOPL. For example, in the second upper interconnection layer UL2, the third upper interconnection layer UL3, the fourth upper interconnection layer UL4, the fifth upper interconnection layer UL5, the sixth upper interconnection layer UL6, the first lower interconnection layer DL1, the second lower interconnection layer DL2, the third lower interconnection layer DL3, the fourth lower interconnection layer DL4, or the fifth lower interconnection layer DL5, a pair of conductive patterns 536P of a pair of differential signal interconnection structures DSL may be located inside the differential signal opening DOPU/DOPL.

The maximum horizontal width of the differential signal opening DOPU/DOPL is a first width W1. The minimum horizontal width of the base board layer 510 located between the equipotential plate 538 and each of the pair of conductive patterns 536P of the pair of differential signal interconnection structures DSL located inside the differential signal opening DOPU/DOPL is a second width W2. The second width W2 may be the minimum spacing between the equipotential plate 538 and each of the pair of conductive patterns 536P of the pair of differential signal interconnection structures DSL located inside the differential signal opening DOPU/DOPL. A horizontal width of each of the pair of conductive patterns 536P of the pair of differential signal interconnection structures DSL is a third width W3. The minimum horizontal width of the base board layer 510 located between the pair of conductive patterns 536P of the pair of differential signal interconnection structures DSL located inside the differential signal opening DOPU/DOPL is a fourth width W4. The fourth width W4 may be a distance between the pair of conductive patterns 536P of the pair of differential signal interconnection structures DSL located inside the differential signal opening DOPU/DOPL.

Referring to FIGS. 2 and 3B together, the equipotential plate 538 may have the differential signal opening DOPU/DOPL. The pair of differential signal interconnection structures DSL may be located inside the differential signal opening DOPU/DOPL. For example, in the first upper interconnection layer UL1 or the sixth lower interconnection layer DL6, a pair of board top pads 532 or a pair of board bottom pads 534 of the pair of differential signal interconnection structures DSL may be located inside the differential signal opening DOPU/DOPL.

The maximum horizontal width of the differential signal opening DOPU/DOPL is the first width W1. The minimum horizontal width of the base board layer 510 located between the equipotential plate 538 and each of the pair of board top pads 532 or the pair of board bottom pads 534 of the pair of differential signal interconnection structure DSL located inside the differential signal opening DOPU/DOPL is a fifth width W5. The fifth width W5 may be the minimum spacing between the equipotential plate 538 and each of the pair of board top pads 532 or the pair of board bottom pads 534 of the pair of differential signal interconnection structure DSL located inside the differential signal opening DOPU/DOPL. A horizontal width of each of the pair of board top pads 532 or the pair of board bottom pads 534 of the pair of differential signal interconnection structures DSL is a sixth width W6. The minimum horizontal width of the base board layer 510 located between the pair board top pads 532 or the pair of board bottom pads 534 of the pair of differential signal interconnection structure DSL located inside the differential signal opening DOPU/DOPL is a seventh width W7. The seventh width W7 may be a spacing between the pair board top pads 532 or the pair of board bottom pads 534 of the pair of differential signal interconnection structure DSL located inside the differential signal opening DOPU/DOPL.

Referring to FIGS. 2 and 3C together, the equipotential plate 538 may have the differential signal opening DOPU/DOPL. The maximum horizontal width of the differential signal opening DOPU/DOPL is the first width W1. Each of the pair of conductive vias 536V of the pair of differential signal interconnection structure DSL may be horizontally spaced apart from the equipotential plate 538 by at least an eighth width W8 planarly. A horizontal width of each of the pair of conductive vias 536V of the pair of differential signal interconnection structures DSL is a ninth width W9. The pair of conductive patterns 536P of the pair of differential signal interconnection structures DSL may be spaced apart from each other by at least a tenth width W10 planarly.

Referring to FIGS. 2 and 3D together, the equipotential plate 538 may have the single signal opening SOP. A single signal interconnection structure SSL may be located inside the single signal opening SOP. For example, the board top pad 532, the board bottom pad 534, or the conductive pattern 536P of the single signal interconnection structure SSL may be located inside the single signal opening SOP.

A horizontal width of the single signal opening SOP is an eleventh width W11. The minimum horizontal width of the base board layer 510 located between each of the board top pad 532, the board bottom pad 534, and the conductive pattern 536P of the single signal interconnection structure SSL located inside the single signal opening SOP and the equipotential plate 538 is a twelfth width W12. The twelfth width W12 may be the minimum spacing between each of the board top pad 532, the board bottom pad 534, and the conductive pattern 536P of the single signal interconnection structure SSL located inside the single signal opening SOP and the equipotential plate 538. A horizontal width of each of the board top pad 532, the board bottom pad 534, or the conductive pattern 536P of the single signal interconnection structure SSL is a thirteenth width W13.

Referring to FIGS. 3A to 3D together, each of the upper differential signal openings DOPU and the lower differential signal openings DOPL may have an elliptical shape planarly. In an embodiment, a horizontal width of each of the upper differential signal openings DOPU and the lower differential signal openings DOPL in the major axis direction has the same first width W1. Each of the upper differential signal openings DOPU and the lower differential signal openings DOPL may be vertically aligned and overlap each other. In some embodiments, the first width W1 may range from about 1500 μm to about 2000 μm.

The minimum spacing between each of the pair of differential signal interconnection structures DSL located inside the differential signal opening DOPU/DOPL and the equipotential plate 538 may be the second width W2, the fifth width W5, or the eighth width W8. In an embodiment, the fifth width W5 is less than the second width W2, and the second width W2 is less than the eighth width W8. The fifth width W5 may range from about 50 μm to about 100 μm. The second width W2 may range from about 200 μm to about 250 μm. The eighth width W8 may range from about 300 μm to about 350 μm.

In an embodiment, the sixth width W6 is greater than the third width W3, and the third width W3 is greater than the ninth width W9. The sixth width W6 may range from about 500 μm to about 700 μm, the third width W3 may range from about 200 μm to about 400 μm, and the ninth width W9 may range from about 50 μm to about 150 μm.

In an embodiment, the tenth width W10 is greater than the fourth width W4, and the fourth width W4 is greater than the seventh width W7. In an embodiment, the seventh width W7 is greater than the ninth width W9. For example, the seventh width W7 may be greater than 300 μm.

The single signal opening SOP may have a circular shape planarly. The diameter of the single signal opening SOP has the eleventh width W11, and the board top pad 532, the board bottom pad 534, or the conductive pattern 536P of the single signal interconnection structure SSL located inside the single signal opening SOP are horizontally spaced apart from the equipotential plate 538 by the twelfth width W12. The board top pad 532, the board bottom pad 534, or the conductive pattern 536P of the single signal interconnection structure SSL located inside the single signal opening SOP may have a thirteenth width W13. In an embodiment, the eleventh width W11 is less than the first width W1. When a portion of the single signal interconnection structure SSL located inside the single signal opening SOP is the board top pad 532 or the board bottom pad 534, the thirteenth width W13 may be substantially equal to the third width W3, and in the case of the conductive pattern 536P, the thirteenth width W13 may be substantially equal to the sixth width W6. The twelfth width W12 inside each of the single signal openings SOP may have the same or substantially the same value. In an embodiment, the twelfth width W12 has a value equal to or less than the fifth width W5. The eleventh width W11, which is the diameter of each of the single signal openings SOPs, may vary depending on a portion of the single signal interconnection structure SSL located inside the single signal openings SOP. For example, the eleventh width W11 may be proportional to the thirteenth width W13. In an embodiment, the eleventh width W11 is less than the first width W1.

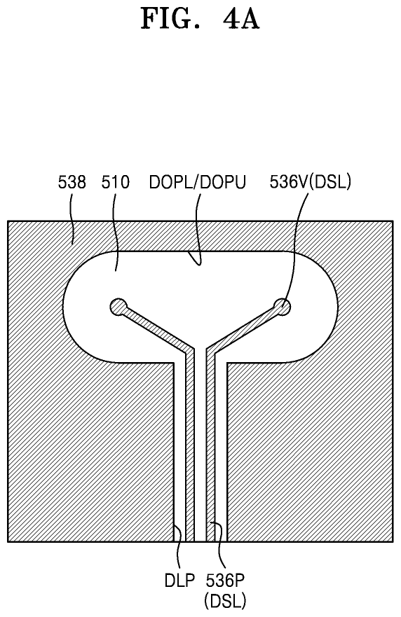

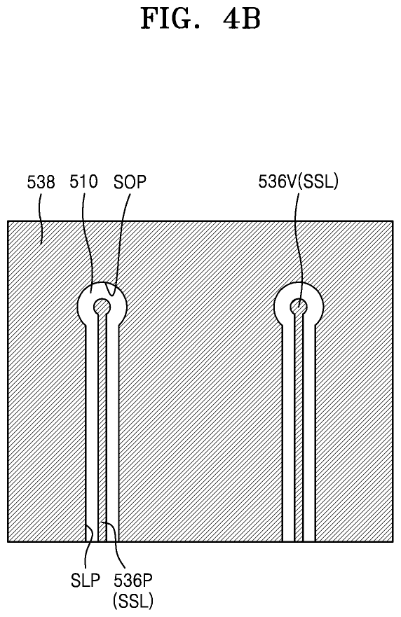

FIGS. 4A and 4B are planar layouts illustrating a portion of a PCB according to embodiments.

Referring to FIGS. 2 and 4A together, a pair of differential signal interconnection structures DSL may extend in the horizontal direction in at least one of the interconnection layers LY. For example, the pair of differential signal interconnection structures DSL may extend along a differential signal interconnection opening DLP communicating with the differential signal openings DOPU and DOPL. In the pair of differential signal interconnection structures DSL, a conductive pattern 536P connected to a conductive via 536V located inside the differential signal openings DOPU and DOPL may be spaced apart from the equipotential plate 538 and extend horizontally along the differential signal openings DOPU and DOPL and the differential signal interconnection opening DLP.

Referring to FIGS. 2 and 4B, the single signal interconnection structure SSL may extend in the horizontal direction in at least one of the interconnection layers LY. For example, the single signal interconnection structure SSL may extend along the single signal interconnection opening SLP communicating with the single signal opening SOP. In the single signal interconnection structure SSL, the conductive pattern 536P connected to the conductive via 536V located inside the single signal opening SOP may be spaced apart from the equipotential plate 538 and horizontally extend along the single signal opening SOP and the single signal interconnection opening SLP.

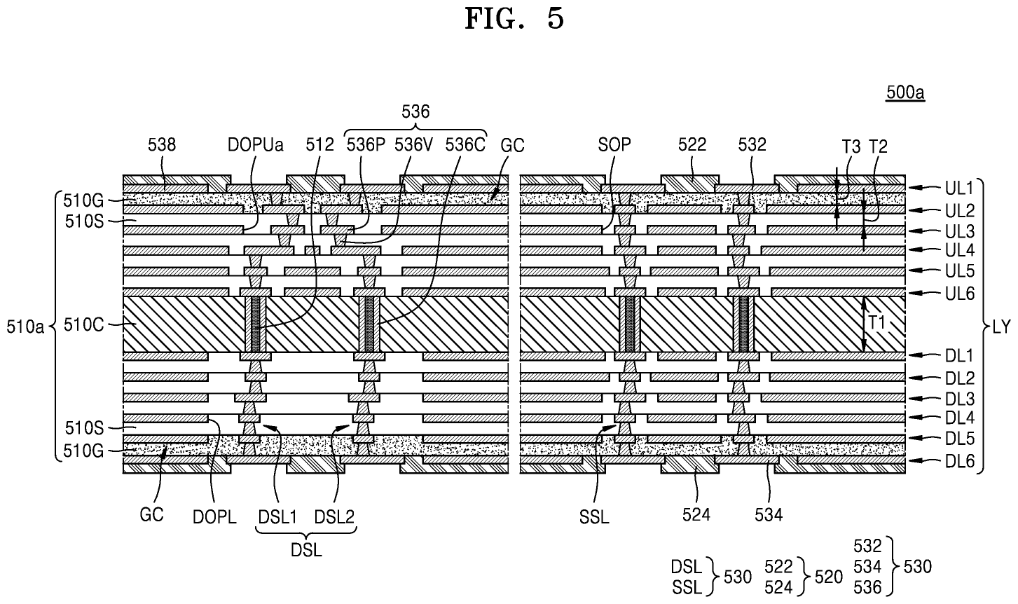

FIG. 5 is a partial cross-sectional view of a PCB 500a according to an embodiment.

Referring to FIG. 5, the PCB 500a may include a base board layer 510a and a substrate interconnection structure 530 disposed on upper and lower surfaces of the base board layer 510a and inside the base board layer 510a. The PCB 500a may further include a plurality of equipotential plates 538 disposed on at least some of the interconnection layers LY. The equipotential plates 538 may have a plurality of differential signal openings DOPUa and DOPL and a plurality of single signal openings SOP. The differential signal openings DOPUa and DOPL may include a plurality of upper differential signal openings DOPUa and a plurality of lower differential signal openings DOPLa. The equipotential plates 538 located above a core board layer 510C may have the upper differential signal openings DOPUa, and the equipotential plates 538 located below the core board layer 510C may have the lower differential signal openings DOPLa.

The lower differential signal openings DOPL may be substantially the same as the lower differential signal openings DOPL shown in FIG. 2. In an embodiment, each of the lower differential signal openings DOPL have the same or substantially the same horizontal width. The lower differential signal openings DOPL may be aligned with each other in the vertical direction and may overlap each other.

In an embodiment, unlike the upper differential signal opening DOPU shown in FIG. 2, the upper differential signal openings DOPUa have a shape similar to that of the single signal openings SOP. In an embodiment, the upper differential signal opening DOPUa disposed on at least one interconnection layer LY among the upper differential signal openings DOPUa have a horizontal width that is different from that of the upper differential signal opening DOPUa disposed on the other at least one interconnection layer LY. In some embodiments, the conductive pattern 536P, the board top pad 532, or the board bottom pad 534 of one differential signal interconnection structure among the first differential signal interconnection structure DSL1 and the second differential signal interconnection structure DSL2 including a pair of differential signal interconnection structures DSL may be located inside each of the upper differential signal openings DOPUa. For example, an edge of the conductive pattern 536P, the board top pad 532, or the board bottom pad 534 of any one of the pair of differential signal interconnection structures DSL located in each of the upper differential signal openings DOPUa may be spaced apart from an edge of the equipotential plate 538 defining each of the upper differential signal openings DOPUa at substantially equal intervals. In some embodiments, a horizontal width of each of the upper differential signal openings DOPUa may be proportional to the horizontal width of the conductive pattern 536P, the board top pad 532, or the board bottom pad 534 located inside each of the upper differential signal openings DOPUa. In some embodiments, a horizontal width of at least some of the upper differential signal openings DOPUa has a value less than that of the horizontal width of each of the lower differential signal openings DOPL.

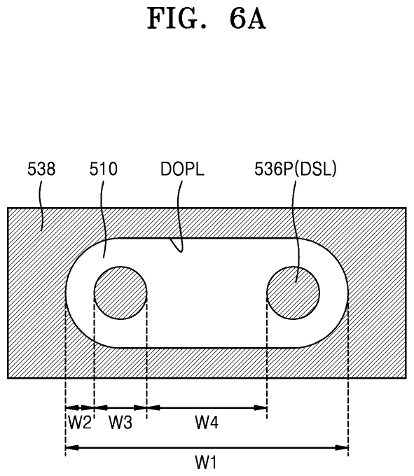

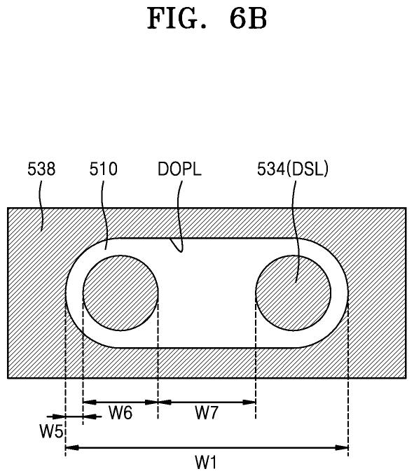

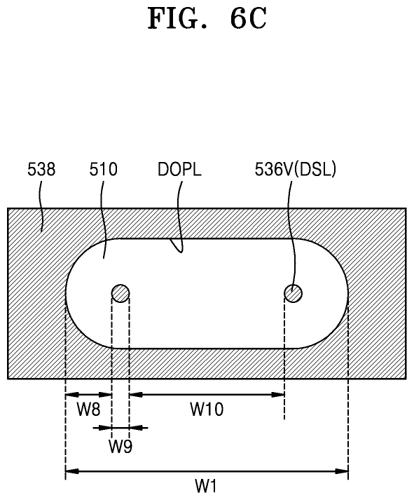

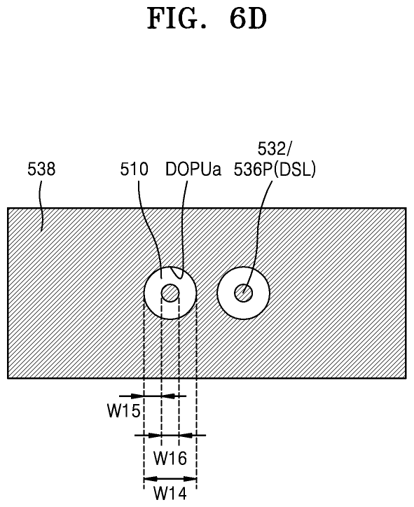

FIGS. 6A to 6D are planar layouts illustrating a portion of the PCB 500a according to embodiments.

Referring to FIG. 5 and FIGS. 6A to 6C together, the equipotential plate 538 may have a lower differential signal opening DOPL. A pair of differential signal interconnection structures DSL may be located inside the lower differential signal opening DOPL. For example, the pair of conductive patterns 536P of the pair of differential signal interconnection structures DSL may be located inside the differential signal openings DOPU/DOPL in the first lower interconnection layer DL1, the second lower interconnection layer DL2, the third lower interconnection layer DL3, the fourth lower interconnection layer DL4, or the fifth lower interconnection layer DL5, and the pair of board bottom pads 534 of the pair of differential signal interconnection structures DSL may be located inside the lower differential signal opening DOPL in the sixth lower interconnection layer DL6.

The lower differential signal opening DOPL shown in FIGS. 6A to 6C may have substantially the same shape as that of the lower differential signal opening DOPL shown in FIGS. 3A to 3C.

Referring to FIGS. 5 and 6D together, the equipotential plate 538 may have the upper differential signal opening DOPUa. One of the pair of differential signal interconnection structures DSL may be located inside the upper differential signal opening DOPUa. For example, the board top pad 532 or the conductive pattern 536P of any one of the pair of differential signal interconnection structures DSL may be located inside the upper differential signal opening DOPUa.

A horizontal width of the upper differential signal opening DOPUa is a fourteenth width W14. For example, a diameter of the upper differential signal opening DOPUa may be the fourteenth width W14. The minimum horizontal width of the base board layer 510 located between the equipotential plate 538 and each of the board top pad 532 and the conductive pattern 536P of any one of the pair of differential signal interconnection structures DSL located inside the upper differential signal opening DOPUa is a fifteenth width W15. The fifteenth width W15 may be the minimum spacing between equipotential plate 538 and each of the board top pad 532 and the conductive pattern 536P located inside any one of the pair of differential signal interconnection structures DSL. A horizontal width of each of the board top pad 532 and the conductive pattern 536P of any one of the pair of differential signal interconnection structures DSL may be a sixteenth width W16. In an embodiment, the fourteenth width W14, the fifteenth width W15, and the sixteenth width W16 are the same or substantially the same as the eleventh width W11, the twelfth width W12, and the thirteenth width W13. In an embodiment, the fourteenth width W14 is less than the first width W1 shown in FIGS. 6A to 6D.

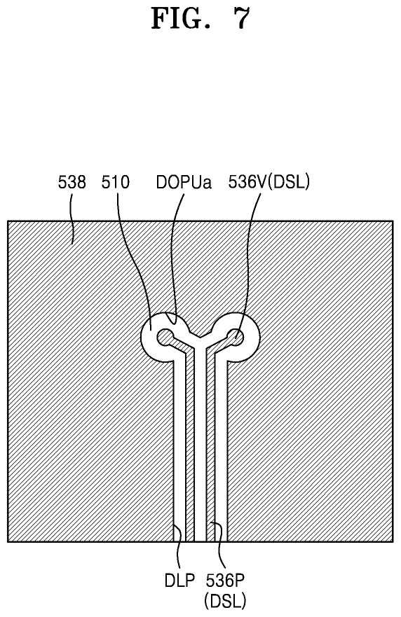

FIG. 7 is a planar layout illustrating a portion of a PCB according to embodiments.

Referring to FIGS. 5 and 7 together, the pair of differential signal interconnection structures DSL may extend in the horizontal direction in at least one of the first upper interconnection layer UL1, the second upper interconnection layer UL2, the third upper interconnection layer UL3, the fourth upper interconnection layer UL4, the fifth upper interconnection layer UL5, and the sixth upper interconnection layer UL6. For example, the pair of differential signal interconnection structures DSL may extend along the differential signal interconnection opening DLP communicating with the pair of upper differential signal openings DOPUa. The pair of upper differential signal openings DOPUa corresponding to the pair of differential signal interconnection structures DSL may communicate with each other through the differential signal interconnection opening DLP. In each of the pair of differential signal interconnection structures DSL, the conductive pattern 536P connected to the conductive via 536V located inside each of the pair of upper differential signal openings DOPUa may be spaced apart from the equipotential plate 538 and horizontally extend along each of the pair of upper differential signal openings DOPUa and the differential signal interconnection opening DLP.

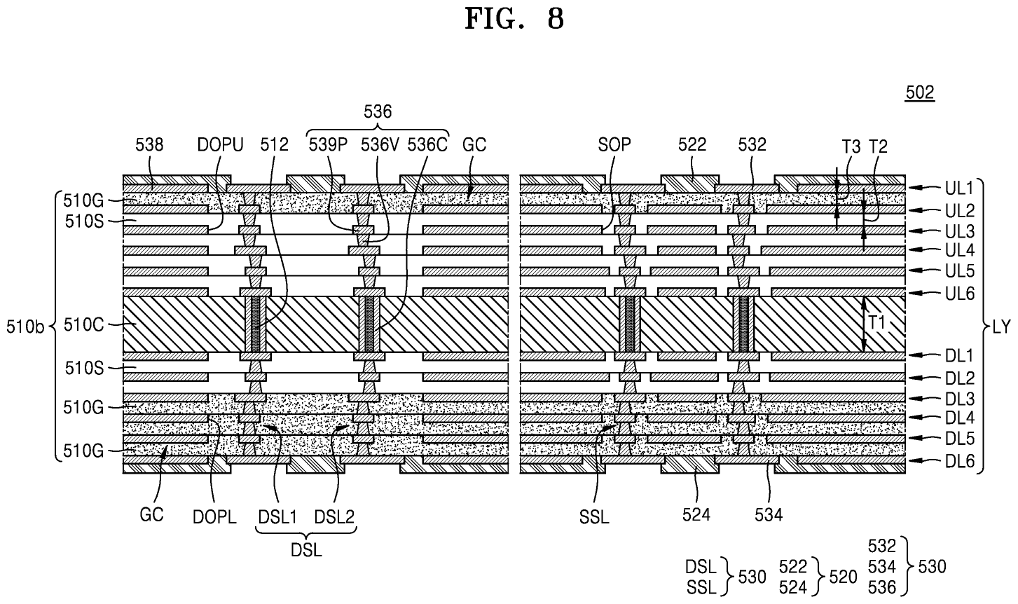

FIGS. 8 to 11 are partial cross-sectional views of PCBs 502, 502a, 504, and 504a according to embodiments.

Referring to FIG. 8, the PCB 502 may include a base board layer 510b and a substrate interconnection structure 530 disposed on upper and lower surfaces of the base board layer 510b and inside the base board layer 510b.

The base board layer 510b may be formed by stacking a plurality of board layers. The board layers may include the core board layer 510C, the sub-board layers 510S, and the reinforcing board layers 510G. Unlike the base board layer 510 shown in FIG. 2 that includes a single reinforcing board layer 510G disposed at the lowermost end, the base board layer 510b shown in FIG. 8 includes at least two reinforcing board layers 510G at the lowermost end. For example, the base board layer 510b may sequentially include the reinforcing board layer 510G, at least one sub-board layer 510S, the core board layer 510C, at least one sub-board layer 510S, and at least two reinforcing board layers 510G sequentially stacked from top to bottom.

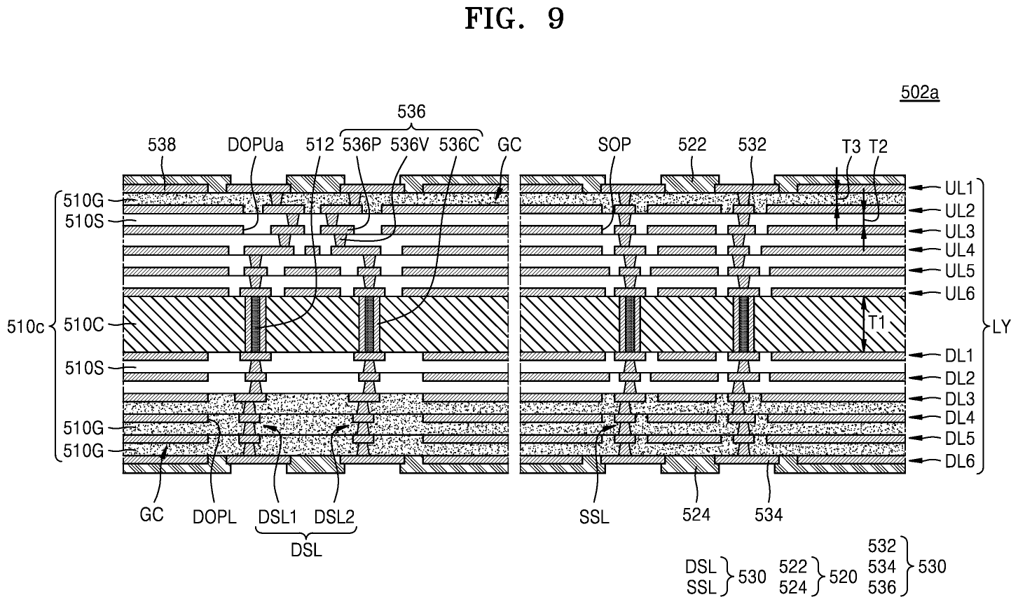

Referring to FIG. 9, the PCB 502a may include a base board layer 510c and a substrate interconnection structure 530 disposed on upper and lower surfaces of the base board layer 510c and inside the base board layer 510c.

The base board layer 510c may be formed by stacking a plurality of board layers. The board layers may include the core board layer 510C, the sub-board layers 510S, and the reinforcing board layers 510G. Unlike the base board layer 510a shown in FIG. 5 that includes a single reinforcing board layer 510G at the lowermost end, the base board layer 510c shown in FIG. 9 includes at least two reinforcing board layers 510G at the bottom. For example, the base board layer 510c may include the reinforcing board layer 510G, at least one sub-board layer 510S, the core board layer 510C, at least one sub-board layer 510S, and at least two reinforcing board layers 510G sequentially stacked from top to bottom.

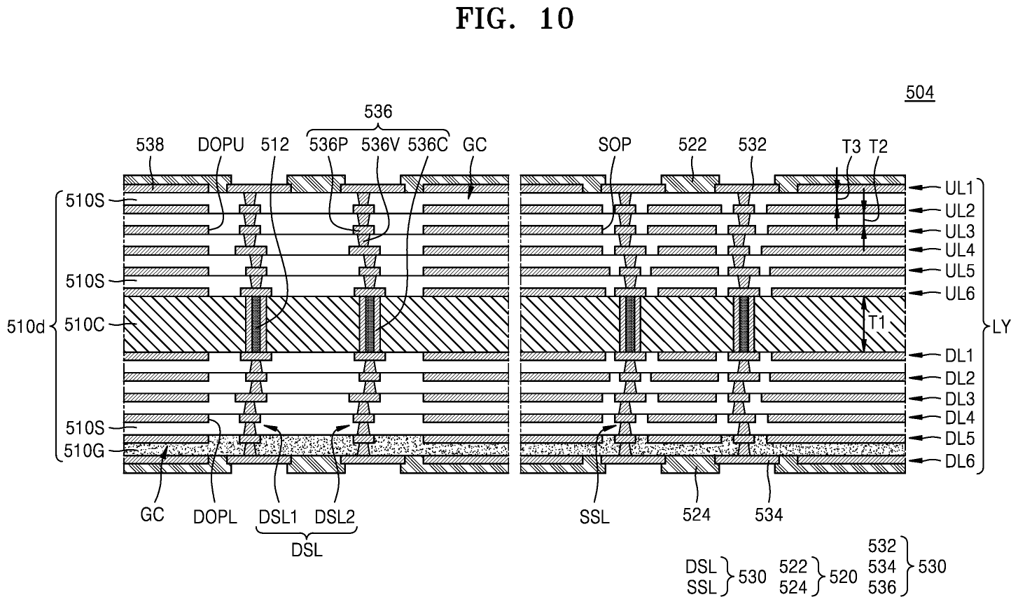

Referring to FIG. 10, the PCB 504 may include a base board layer 510d and a substrate interconnection structure 530 disposed on upper and lower surfaces of the base board layer 510d and inside the base board layer 510d.

The base board layer 510d may be formed by stacking a plurality of board layers. The board layers may include the core board layer 510C, the sub-board layers 510S, and the reinforcing board layer 510G. Unlike the base board layer 510 shown in FIG. 2 that includes one reinforcing board layer 510G at each of the uppermost end and the lowermost end thereof, in the base board layer 510d shown in FIG. 10, the sub-board layer 510S may be located at the uppermost end and the reinforcing board layer 510G is located only at the lowermost end. For example, the base board layer 510d may include at least one sub-board layer 510S, the core board layer 510C, at least one sub-board layer 510S, and one reinforcing board layer 510G sequentially stacked from top to bottom.

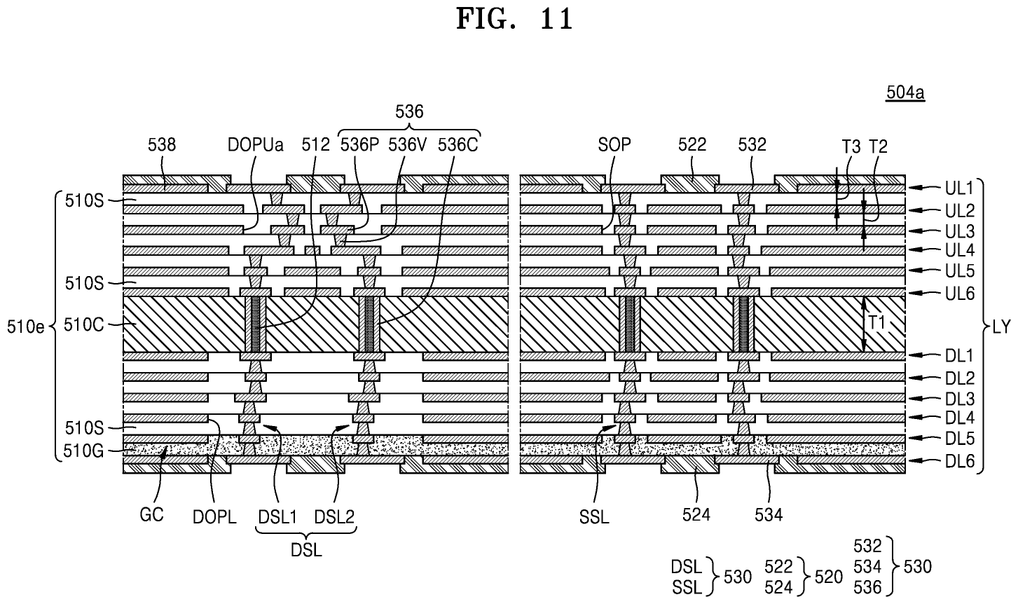

Referring to FIG. 11, the PCB 504a may include a base board layer 510e and a substrate interconnection structure 530 disposed on upper and lower surfaces of the base board layer 510e and inside the base board layer 510c.

The base board layer 510e may be formed by stacking a plurality of board layers. The board layers may include the core board layer 510C, the sub-board layers 510S, and the reinforcing board layer 510G. Unlike the base board layer 510a shown in FIG. 5 including one reinforcing board layer 510G at each of the uppermost end and the lowermost end thereof, in the base board layer 510e shown in FIG. 11, the sub-board layer 510S may be located at the uppermost end and the reinforcing board layer 510G is located only at the lowermost end. For example, the base board layer 510a may include at least one sub-board layer 510S, the core board layer 510C, at least one sub-board layer 510S, and one reinforcing board layer 510G sequentially stacked from top to bottom.

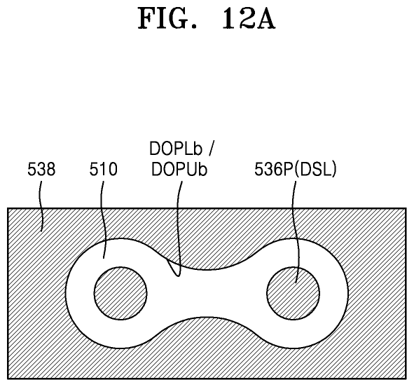

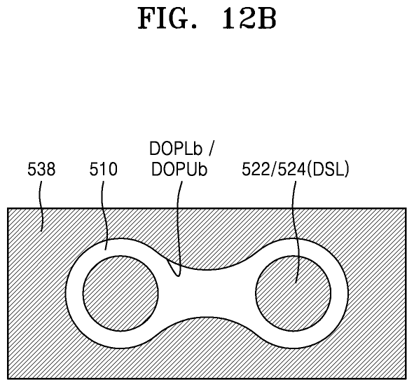

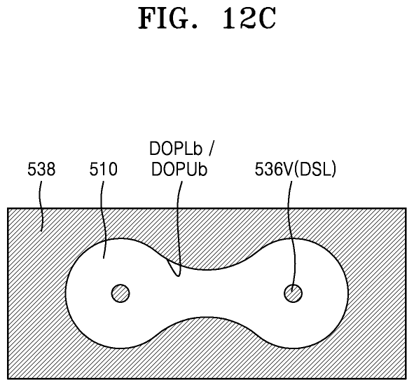

FIGS. 12A to 12C are planar layouts illustrating a portion of a PCB according to embodiments.

Referring to FIGS. 12A to 12C together, the equipotential plate 538 may have a differential signal opening DOPUb/DOPLb. A pair of differential signal interconnection structures DSL may be located inside the differential signal opening DOPUb/DOPLb. The differential signal openings DOPUb and DOPLb may include an upper differential signal opening DOPUb and a lower differential signal opening DOPLb.

Unlike the differential signal openings DOPU/DOPL shown in FIGS. 3A to 3C having an elliptical shape planarly, the differential signal opening DOPUb/DOPLb shown in FIGS. 12A to 12C have a dumbbell shape or a snowman shape planarly. For example, the differential signal opening DOPUb/DOPLb may have a planar shape with a concave portion toward a space between the pair of differential signal interconnection structures DSL located inside the differential signal opening DOPUb/DOPLb.

While the inventive concept has been particularly shown and described with reference to embodiments thereof, it will be understood that various changes in form and details may be made therein without departing from the spirit and scope of the following claims.

What is claimed is:

1. A printed circuit board comprising:
a base board layer including a plurality of board layers which are stacked, the plurality of board layers including a core board layer, a plurality of sub-board layers stacked on each of upper and lower surfaces of the core board layer, and at least one reinforcing board layer;
a plurality of equipotential plates disposed on a plurality of interconnection layers located on upper and lower surfaces of the plurality of board layers and having differential signal openings and single signal openings; and
a substrate interconnection structure including a plurality of board top pads disposed on the upper surface of the base board layer, a plurality of board bottom pads disposed on the lower surface of the base board layer, and a plurality of board interconnection paths connecting the plurality of board top pads to the plurality of board bottom pads through the base board layer,
wherein the plurality of board top pads, the plurality of board bottom pads, and the plurality of board interconnection paths included in the substrate interconnection structure configure a pair of differential signal interconnection structures extending inside the differential signal openings of the plurality of equipotential plates and a single signal interconnection structure extending inside the single signal openings of the plurality of equipotential plates,
wherein lower differential signal openings, which are the differential signal openings of the equipotential plates located below the core board layer, among the plurality of equipotential plates, have a same horizontal width and are aligned with each other in a vertical direction, and
wherein the at least one reinforcing board layer comprises a first reinforcing board layer stacked on a lower surface of a lowermost sub-board layer among the plurality of sub-board layers.

2. The printed circuit board of claim 1, wherein the at least one reinforcing board layer further comprises a second reinforcing board layer stacked on an upper surface of an uppermost sub-board layer among the plurality of sub-board layers.

3. The printed circuit board of claim 1, wherein the at least one reinforcing board layer further comprises a second reinforcing board layer, and the first and second reinforcing board layers are stacked on the lower surface of the lowermost sub-board layer.

4. The printed circuit board of claim 1, wherein upper differential signal openings, which are differential signal openings of the equipotential plates located on the core board layer, have the same horizontal width and are aligned with each other in the vertical direction.

5. The printed circuit board of claim 4, wherein the upper differential signal openings and the lower differential signal openings have a same horizontal width and are aligned with each other in the vertical direction.

6. The printed circuit board of claim 1, wherein, among the upper differential signal openings, which are the differential signal openings of the equipotential plates located on the core board layer, among the plurality of equipotential plates, an upper differential signal opening disposed on at least one interconnection layer different from an upper differential signal opening disposed on at least one interconnection layer, among the plurality of interconnection layers has a different horizontal width.

7. The printed circuit board of claim 6, wherein horizontal widths of at least some of the upper differential signal openings have a value less than horizontal widths of the lower differential signal openings.

8. The printed circuit board of claim 1, wherein horizontal widths of at least some of the single signal openings have a value less than horizontal widths of the lower differential signal openings.

9. The printed circuit board of claim 1, wherein the at least one reinforcing board layer includes a reinforcing member including glass cloth.

10. The printed circuit board of claim 1, wherein
the core board layer has a first thickness, each of the plurality of sub-board layers has a second thickness, and the reinforcing board layer has a third thickness, and
the first thickness has a value greater than each of the second thickness and the third thickness.

11. A printed circuit board comprising:
a base board layer including a plurality of board layers which are stacked, the plurality of board layers including a core board layer having a first thickness, a plurality of sub-board layers stacked on each of upper and lower surfaces of the core board layer and having a second thickness that is less than the first thickness, and at least one reinforcing board layer having a third thickness that is less than the first thickness;
a plurality of equipotential plates disposed on a plurality of interconnection layers located on upper and lower surfaces of the plurality of board layers and having differential signal openings and single signal openings;
a substrate interconnection structure including a plurality of board top pads disposed on the upper surface of the base board layer, a plurality of board bottom pads disposed on the lower surface of the base board layer, and a plurality of board interconnection paths connecting the plurality of board top pads to the plurality of board bottom pads through the base board layer and including a plurality of conductive vias passing through a plurality of conductive patterns disposed on the plurality of interconnection layers and the plurality of board layers; and
a solder resist layer covering the upper and lower surfaces of the base board layer and exposing the plurality of board top pads and the plurality of board bottom pads,
wherein the plurality of board top pads, the plurality of board bottom pads, and the plurality of board interconnection paths included in the substrate interconnection structure configure a pair of differential signal interconnection structures spaced apart from the plurality of equipotential plates and extending inside the differential signal openings of the plurality of equipotential plates and a single signal interconnection structure spaced apart from the plurality of equipotential plates and extending inside the single signal openings of the plurality of equipotential plates,
wherein lower differential signal openings, which are the differential signal openings of the equipotential plates located below the core board layer, among the plurality of equipotential plates, have a same horizontal width and are aligned with each other in a vertical direction,
wherein a horizontal width of a first one of the single signal openings disposed in at least one interconnection layer, among the single signal openings, is different from a horizontal width of a second other one of the single signal openings disposed in the at least one interconnection layer, and
wherein the at least one reinforcing board layer comprises a first reinforcing board layer stacked on a lower surface of a lowermost sub-board layer among the plurality of sub-board layers.

12. The printed circuit board of claim 11, wherein the at least one reinforcing board layer includes glass cloth, and the plurality of sub-board layers do not include glass cloth.

13. The printed circuit board of claim 11, wherein the lower differential signal openings have an elliptical shape planarly, and the single signal openings have a circular shape planarly.

14. The printed circuit board of claim 11, wherein the at least one reinforcing board layer further comprises a second reinforcing board layer stacked on an upper surface of an uppermost sub-board layer among the plurality of sub-board layers.

15. The printed circuit board of claim 11, wherein the at least one reinforcing board layer further comprises second and third reinforcing board layers, the second reinforcing board layer stacked on an upper surface of an uppermost sub-board layer, among the plurality of sub-board layers, and the first and third reinforcing board layers stacked on the lower surface of the lowermost sub-board layer.

16. The printed circuit board of claim 11, wherein upper differential signal openings, which are differential signal openings of the equipotential plates located on the core board layer, and the lower differential signal openings have the same horizontal width and are aligned with each other in the vertical direction.

17. The printed circuit board of claim 11, wherein a horizontal width of at least one of the upper differential signal openings, which are the differential signal openings of the equipotential plates located on the core board layer among the plurality of equipotential plates, has a value that is less than a value of horizontal widths of the lower differential signal openings.

18. A semiconductor package comprising:
a printed circuit board including:
a substrate interconnection structure including a base board layer comprising a plurality of board layers which are stacked;
a plurality of equipotential plates disposed on a plurality of interconnection layers located on upper and lower surfaces of the plurality of board layers and having differential signal openings and single signal openings; and
a plurality of board top pads disposed on the upper surface of the base board layer, a plurality of board bottom pads disposed on a lower surface of the base board layer, and a plurality of board interconnection paths connecting the plurality of board top pads to the plurality of board bottom pads, and configuring a pair of differential signal interconnection structures extending inside the differential signal openings of the plurality of equipotential plates and a single signal interconnection structure extending inside the single signal openings of the plurality of equipotential plates;
a plurality of package connection terminals attached to the plurality of board top pads;
an interposer electrically connected to the printed circuit board by the plurality of package connection terminals;
at least one stack structure attached to the interposer and including a first semiconductor chip and a plurality of second semiconductor chips sequentially stacked on the first semiconductor chip in a vertical direction;
at least one third semiconductor chip attached to the interposer and spaced apart from the at least one stack structure in a horizontal direction; and
a plurality of external connection terminals attached to the plurality of board bottom pads,
wherein the differential signal openings of at least some of the plurality of equipotential plates have the same horizontal width and are aligned with each other in the vertical direction, and
wherein the plurality of board layers include a core board layer, a plurality of sub-board layers stacked on each of upper and lower surfaces of the core board layer, and a lower reinforcing board layer stacked on a lower surface of a lowermost sub-board layer, among the plurality of sub-board layers, and including glass cloth.

19. The semiconductor package of claim 18, wherein
all lower differential signal openings of equipotential plates located below the core board layer, among the lower differential signal openings, have the same horizontal width and are aligned with each other in the vertical direction, and
a horizontal width of a first one of the single signal openings disposed in at least one interconnection layer, among the plurality of interconnection layers is different from a horizontal width of a second other one of the single signal openings disposed in at the least one interconnection layer, among the plurality of interconnection layers.

20. The semiconductor package of claim 18, wherein
the plurality of board layers further include an upper reinforcing board layer stacked on an upper surface of an uppermost sub-board layer among the plurality of sub-board layers and including glass cloth, and
the lower reinforcing board layer includes at least two lower reinforcing board layers stacked on the lower surface of the lowermost sub-board layer.
